(19) United States
(12) Patent Application Publication
(10) Pub. No.: US 2025/0062727 A1
(43) Pub. Date: Feb. 20, 2025

(54) SYSTEM AND METHOD FOR MEASURING AN AUDIO PATH DELAY FOR AN AMPLIFIER

(71) Applicant: Harman International Industries, Incorporated, Stamford, CT (US)

(72) Inventor: Zhijun CHEN, Kanagawa (JP)

(21) Appl. No.: 18/234,667

(22) Filed: Aug. 16, 2023

(51) Int. Cl. H03F 3/183; H04R 5/04

(52) U.S. Cl. CPC H03F 3/183; H04R 5/04; H03F 2200/03

(57) ABSTRACT

An audio system for measuring a delay is provided. The audio system includes an audio controller, an amplifier, a first digital to analog converter, and a measurement controller. The audio controller is programmed to transmit an audio input signal in a digital domain. The amplifier is programmed to process the audio input signal and to convert the processed audio input signal into a first processed audio signal in an analog domain. The amplifier is further programmed to amplify the first processed audio signal to provide an amplified audio output signal in the analog domain and to output the amplified audio output signal to drive one or more loudspeakers. The first digital to analog converter is programmed to convert the processed audio input signal into a second processed signal in the analog domain. The measurement controller is further programmed to determine a delay for the amplifier.

### TECHNICAL FIELD

Aspects disclosed herein generally relate to a system and a method for measuring an audio path delay for an amplifier. This aspect and others will be discussed in more detail below.

### BACKGROUND

Audio systems generally include an electronic control unit (“ECU”) (e.g., audio head unit or audio controller), an amplifier, and at least one loudspeaker. An audio interface is provided and positioned between the ECU and the amplifier to communicate (or provide) an audio input signal to the amplifier. In turn, the amplifier may amplify the audio input signal such that the loudspeaker transmits the amplified audio input signal into a listening environment. A data channel bus (or digital bus) may transmit the audio input signal from the ECU, digitally, to the amplifier at a rapid rate. However, the amplifier provides the amplified audio input signal to the loudspeaker in an analog format. It may be desirable to measure the amount of time that the amplifier processes the audio input signal relative to when the loudspeaker plays back the amplified audio signal in the listening environment. In some case, this may be difficult to perform.

### SUMMARY

In at least one embodiment, an audio system for measuring a delay is provided. The audio system includes an audio controller, an amplifier, a network to analog converter, and a measurement controller. The audio controller is programmed to transmit an audio input signal in a digital domain. The amplifier is programmed to process the audio input signal and to convert the processed audio input signal into a first processed audio signal in an analog domain. The amplifier is further programmed to amplify the first processed audio signal to provide an amplified audio output signal in the analog domain and to output the amplified audio output signal to drive one or more loudspeakers. The network to analog converter is programmed to convert the processed audio input signal into a second processed audio signal in the analog domain. The measurement controller is further programmed to determine a delay for the amplifier to (i) process the audio input signal, (ii) convert the processed audio input signal into the first processed audio signal, (iii) amplify the first processed audio signal, and (iv) output the amplified audio output signal based at least on the first processed audio signal being in the analog domain and the outputted amplified audio output signal being in the analog domain.

In at least another embodiment, a method for measuring a delay in an audio system is provided. The method includes transmitting an audio input signal in a digital domain and processing, at an amplifier, the audio input signal. The method further includes converting the processed audio input signal into a first processed audio signal in an analog domain and amplifying, by the amplifier, the first processed audio signal to provide an amplified audio output signal in the analog domain. The method further includes outputting the amplified audio output signal to drive one or more loudspeakers; and converting, by a network to analog converter, the processed audio input signal into a second processed audio signal in the analog domain. The method further includes determining a delay for the amplifier to (i) process the audio input signal, (ii) convert the processed audio input signal into the first processed audio signal, (iii) amplify the first processed audio signal, and (iv) output the amplified audio output signal based at least on the first processed audio signal being in the analog domain and the outputted amplified audio output signal being in the analog domain.

In at least another embodiment, a computer-program product embodied in a non-transitory computer readable medium stored in memory that is programmed and executable by at least one controller in an audio system is provided. The computer-program product includes instructions to transmit an audio input signal in a digital domain and to process, at an amplifier, the audio input signal. The computer-program product includes instructions to convert the processed audio input signal into a first processed audio signal in an analog domain and to amplify, by the amplifier, the first processed audio signal to provide an amplified audio output signal in the analog domain. The computer-program product includes instructions to output the amplified audio output signal to drive one or more loudspeakers and to convert, by a network to analog converter, the processed audio input signal into a second processed audio signal in the analog domain. The computer-program product includes instructions to determine a delay for the amplifier to (i) process the audio input signal, (ii) convert the processed audio input signal into the first processed audio signal, (iii) amplify the first processed audio signal, and (iv) output the amplified audio output signal based at least on the first processed audio signal being in the analog domain and the outputted amplified audio output signal being in the analog domain.

### BRIEF DESCRIPTION OF THE DRAWINGS

The embodiments of the present disclosure are pointed out with particularity in the appended claims. However, other features of the various embodiments will become more apparent and will be best understood by referring to the following detailed description in conjunction with the accompany drawings in which:

FIG. 1 generally illustrates one example of an audio system;

FIG. 2 generally illustrates a more detailed implementation with test equipment for measuring a delay of an amplifier of the audio system of FIG. 1;

FIG. 3 generally illustrates a system for measuring an audio path delay in accordance to one embodiment; and

FIG. 4 generally illustrates a method for measuring the audio path delay in accordance to one embodiment.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

It should be understood that the following description of embodiments is provided for illustrative purposes only and not for limiting purposes. The division of examples in functional blocks, controllers, units or other devices shown in the drawings should not be interpreted as indicating that these functional blocks, controllers, units, or other devices must be realized as physically separate units. It is recognized that these functional blocks, controllers, units, or other devices shown or described may be combined or separate in any manner. It is also recognized that that the functional blocks, controllers, units, or other devices may be implemented as circuits, electronic chips, or circuit elements. One or a plurality of the blocks illustrated in the figures may also be implemented in a common circuit, chip, circuit element, or unit.

The use of a singular term (such as, but not limited to, “a”) is not intended to limit the quantity of the item. Use of relational terms such as, but not limited to, “top,” “bottom,” “left,” “right,” “upper,” “lower,” “downward,” “upward,” “lateral,” “first,” “second,” (“third,” and the like), “inlet,” “outlet,” and the like are used in written descriptions for clarity when specific reference is made to the drawings and are not intended to limit the scope of the present disclosure or the appended claims, unless otherwise specified. The terms “including” and “such as” are illustrative rather than restrictive, and the word “can” entails “can, but not necessarily,” unless otherwise stated. Notwithstanding the use of any other language in the present disclosure, the embodiments shown in the accompanying drawings are examples given for purposes of illustration and explanation, and not the only embodiment of the subject matter herein.

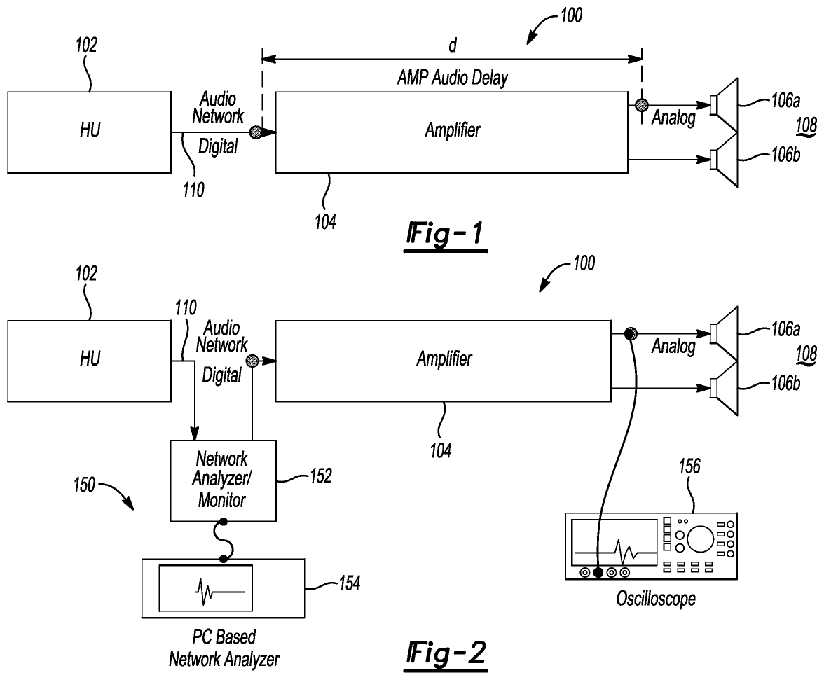

FIG. 1 generally illustrates one example of an audio system 100. The system 100 generally includes a head unit (HU) 102 (e.g., audio controller 102), an amplifier 104, and a plurality of loudspeakers 106a-106b (or “106”). In general, the audio controller 102 transmits an audio input signal to the amplifier 104. In turn, the amplifier 104 processes the audio input signal and transmits an amplified audio output signal to the loudspeakers 106 to playback the input audio signal in a listening environment 108. In one example, the loudspeakers 106 may be configured to play back the input audio signal in a cabin of a vehicle (not shown). It is recognized that the audio system 100 may be utilized for vehicle applications, home theatre applications, etc.

A digital communication bus 110 is positioned between the audio controller 102 and the amplifier 104. Thus, in this regard the audio controller 102 transmits the audio input channel digitally on the digital communication bus 110 to the amplifier 104. The amplifier 104 processes and amplifies the audio input signal to generate a processed and amplified audio input signal. The amplifier 104 transmits the processed and amplified audio input signal as an analog signal to the loudspeaker 106 for playback. It is generally desirable to ascertain the manner in terms of the amount of time (e.g., delay d) it takes for the amplifier 104 to process and output (e.g., including the amplification) the received audio input signal. However, there are challenges in terms of obtaining the delay attributed to the amplifier 104 given that the received audio input signal is transmitted digitally from the audio controller 102 to the amplifier 104 and further that the amplified audio output signal as output from the amplifier 104 is in an analog domain.

FIG. 2 generally illustrates a more detailed implementation with test equipment 150 for measuring a delay of the amplifier 104 of the audio system of FIG. 1. As shown, FIG. 2 includes the audio controller 102, the amplifier 104, the loudspeakers 106, and the test equipment 150. The implementation of the test equipment 150 may be used to determine the delay, d associated with the amplifier 104. The test equipment 150 includes a network analyzer 152, a network analyzer display 154, and an oscilloscope 156. The network analyzer 152 may be operably coupled to the digital communication bus 110. It is recognized that the digital communication bus 110 may enable communication via a Media Oriented Systems Transport (MOST) or Automotive Audio Bus (“A2B”). The network analyzer 152 is configured to monitor bus activity between the audio controller 102 and the amplifier 104 given that the audio controller 102 and the amplifier 104 communicated digitally. The display 154 displays the bus activity on the digital communication bus 110 to a user.

The oscilloscope 156 may be electrically coupled to an output of the amplifier 104 to monitor signal transmission and other aspects related to the transmission of the amplified audio output to the loudspeakers 106. As noted, the amplifier 104 transmits the amplified audio output signal in the analog domain. In this regard, the oscilloscope 156 may be triggered based on the output of the amplifier 104 becoming active. Given that two different measurement sources are being used (e.g., the network analyzer 152 and the oscilloscope 156), it may be difficult to measure the delay, or the amount of time required for the amplifier 104 to process/amplify the received audio input signal. Other reasons for the difficulty in measuring the delay involve, among other things, (i) the two devices (e.g., the network analyzer 152 and the oscilloscope 156) being made by different manufacturers or belonging to different tool vendors, (ii) challenges in synching time stamps on the digitized audio input signal with the output of the analog based audio output signal, (iii) zoom range, and/or (iv) a hard to set trigger for the oscilloscope 156 to measure the audio output signal. In particular, the use of the oscilloscope 156 to measure the output of the amplifier 104 is different from the network analyzer 152 which is used to measure the audio input signal on the digital communication bus 110 and thus there may not be an efficient method to sync the measured audio signal between the network analyzer 152 and the oscilloscope 156.

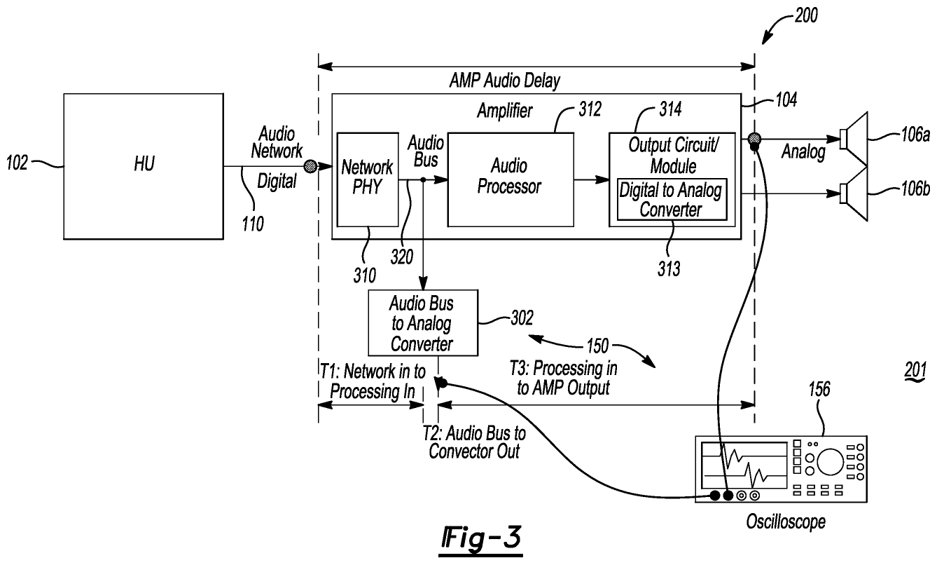

FIG. 3 generally illustrates a system 200 for measuring an audio path delay for the audio system in accordance to one embodiment. The system 200 includes the audio controller 102, the amplifier 104, the plurality of loudspeakers 106, and the test equipment 150. Similar to FIG. 1, the audio controller 102 transmits the audio input signal to the amplifier 104 via the digital communication bus 110 in the digital domain. In addition, the amplifier 104 processes the received audio input signal and amplifies the same. The amplifier 104 then outputs the audio output signal in the analog domain. The test equipment 150 includes an audio bus to analog converter 302 (e.g., first digital to analog converter) and the oscilloscope 156. In this regard, the test equipment 150 may be used to measure the delay in terms of the amount of time required for the amplifier 104 to process the audio input signal), amplify (e.g., the audio input signal) to generate the amplified audio output signal, and output the amplified audio output signal. The system 200 also includes at least one measurement controller 201 (hereafter “the measurement controller 201”) may be operably coupled to the test equipment 150 for providing the delay or amount of time for the amplifier 104 to process the audio input signal, amplify the audio input signal to generate the amplified audio output signal, and to output the amplified audio output signal. This will be discussed in more detail below. It is recognized that the measurement controller 201 may be part of the audio controller 102, the amplifier 104, and/or the test equipment 150.

The amplifier 104 includes a network physical layer 310, an audio processor 312, and an output circuit 314. The network physical layer 310 receives the audio input signal from the audio controller 102 and pre-processes data on the audio input signal before such information is sent to the audio processor 312. The network physical layer 310 generally converts the audio input signal into a digital audio synchronous clock-based signal. In one example, the network physical layer 310 receives the audio input signal and decodes a network management and control signal. The network physical layer 310 receives the audio input signal and transfers the same between an internal portion of the audio controller 102 and a digital audio network. The network physical layer 310 transfers audio data on the audio input signal to the audio bus 320 where the audio bus 320 is primarily internal to an electronic control unit (not shown) in the amplifier 104. The audio input signal once processed by the network physical layer 310 may include a bit clock and Frame Sync along with digital data corresponding to the desired audio data to be played back. The audio bus 320 may facilitate communication in accordance to the following protocols: I²S, time division multiplexing (TDM), etc.

An audio bus 320 is positioned between the network physical layer 310 and the audio processor 312. The audio processor 312 may perform any number of audio processing operations, such as, but not limited to, providing surround sound audio, providing immersive sound, muting, equalization, etc. The type of audio processing operations performed by the audio processor 312 may vary based on different customer requirements. The audio bus to analog converter 302 is coupled to the audio bus 320. In general, the audio bus to analog converter 302 converts digital data as transmitted on the audio bus 320 between the network physical layer 310 and the audio processor 312 into an analog domain. In this regard, the audio bus to analog converter 302 is a digital to analog converter. The output circuit 314 includes a digital to analog converter 313 (or a second digital to analog converter) for converting the digital data prior to the audio output signal being output to the loudspeakers 106. The oscilloscope 156 may be connected to an output of the audio bus to analog converter 302 and to an output of the amplifier 104 and obtain measurement(s) from these position(s).

In general, the amount of time for the network physical layer 310 to process the audio input signal and to output the same on the audio bus 320 may be generally defined by a first time period, such as T1. The first time period, T1 may be a known or fixed value (i.e., determined) as the manufacturer of the network physical layer 310 may provide information with respect to the amount of time that is consumed by the network physical layer 310 to process the audio input signal and to output the same on the audio bus 320. In yet other examples, the oscilloscope 156 may be used to measure the first time period, T1 if such information pertaining to the known or fixed value is not available or inaccurately provided by the manufacturer. The measurement controller 201 may determine (or store) information corresponding to the first time period, T1.

The amount of time for the audio bus to analog converter 302 (e.g., digital to analog converter) to convert the digital data from the audio bus 320 into an analog format may be fixed (or known) and is generally defined by a second time period such as, T2. The information pertaining to the second time period, T2 may also be known or fixed (i.e., determined) based on information provided by manufacturer of the audio bus to analog converter 302. In yet other examples, the oscilloscope 156 may be used to measure the second time period, T2 if such information pertaining to the known or fixed value is not available or inaccurately provided by the manufacturer. The measurement controller 201 may determine (or store) information corresponding to the second time period, T2.

The amount of time required for the amplifier 104 (e.g., the output circuit 314) perform software processing and to amplify the audio input signal to generate the audio output signal and for the output circuit 314 to output the audio output signal is generally defined by a third time period, such as, T3. The output circuit 314 includes any number of amplifiers (e.g., either software and/or hardware-based amplifiers) to amplify the audio output signal in the analog domain and to output the same to the loudspeakers 105. As noted above, the controller 201 may store information corresponding to the first time period, T1 and to the second time period, T2 since these values may be previously known or fixed. The controller 201 may also store information corresponding to the third time period, T3 after the oscilloscope 156 measures this value.

The oscilloscope 156 may be coupled to an output of the audio bus to analog converter 302 to receive an analog version of the processed audio input signal and to an output of the amplifier 104 to receive the analog version of the amplified audio output signal. Given that the output of the audio bus to analog converter 302 outputs an analog signal and the amplifier 104 outputs an analog signal, the oscilloscope 156 measures the two analog signal to determine the second time period, T2 and the third time period, T3. As noted above, the first time period T1 may be fixed and known and is stored in the measurement controller 201. The oscilloscope 156 may transmit the measurement or calculation of the second time period, T2 and the third time period, T3 to the controller 201. In turn, the measurement controller 201 may then sum the first time period, T1; the second time period, T2; and the third time period T2 (e.g., T1+T2+T3) to ascertain the total amount of time (or delay) employed by the amplifier 104 to process the audio input signal, amplify the audio input signal to generate the amplified audio output signal, and output the amplified audio output signal to the loudspeakers 106. The measurement controller 201 may report out the delay attributed to the amplifier 104 to a user via a display (not shown) or other mechanism. It is recognized that various car manufacturers may employ strict requirements with respect to the overall delay employed by the amplifier 104 to receive the audio input signal, amplify the audio input signal to generate the audio output signal, and to output the audio output signal to the loudspeakers 106. The disclosed system 200 enables audio providers the ability to accurately calculate such a delay.

The disclosed system 200 may generally measure the delay associated with the amplifier 104 in processing the audio input signal, amplifying the same, and outputting the amplified audio output signal to the loudspeakers 106. The disclosed system 200 may also determine the delay with network-based audio data (e.g., fixed delay (i.e., first time period, T1 and/or the second time period, T2) and also output the audio output signal in a same time stamp. The disclosed system 200 may also enable the user the ability to view network audio data (e.g., shift a fixed delay) and also view the output of the amplifier 104 in a same zoom. In general, the output of the audio bus to analog converter 302 and the amplifier 104 are both analog, thus it is possible for the oscilloscope 156 to measure the time delays associated with analog output of audio bus to analog converter 302 and the amplifier 104. In this case, the oscilloscope 156 has an input channel capability of >=2. The disclosed system 200 may also execute a trigger for purpose of the oscilloscope 156 triggering the measurement for the outputs of the audio bus to analog converter 302 and of the amplifier 104. The oscilloscope 156 may receive an input from a user to set a certain signal level as a trigger to then start the time measurement of the outputs from the audio bus to analog converter 302 and the amplifier 304. Similarly, the disclosed system 200 may also extend the disclosed operations to perform a general cross signal measurement. In short, the with this extension, the delay measurement may be extended to a Digital Network A in, to a Digital Network B output, or Analog In and a Digital Network output.

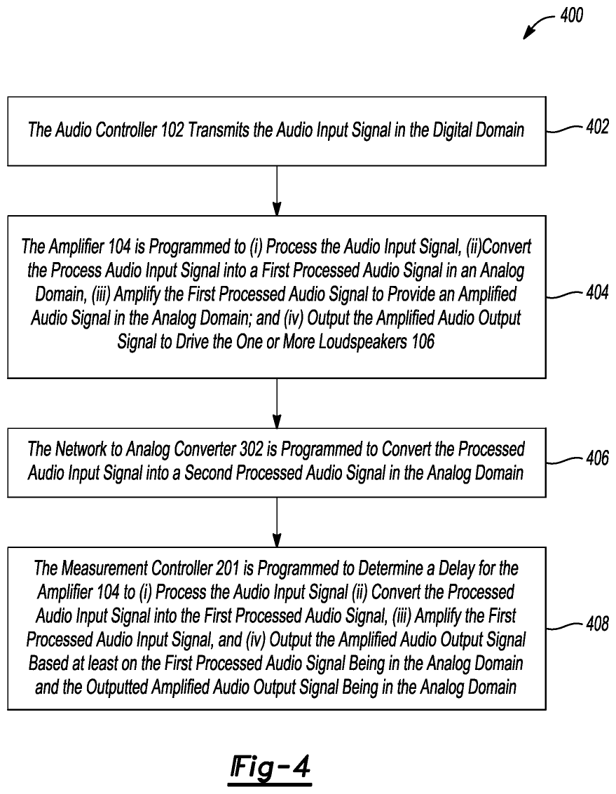

FIG. 4 generally illustrates a method 400 for measuring the audio path delay in accordance to one embodiment.

In operation 402, the audio controller 102 is programmed to transmit the audio input signal in the digital domain.

In operation 404, the amplifier 104 is programmed to (i) process, via the network physical layer 310, the audio input signal, (ii) convert the processed audio input signal into a first processed audio signal in an analog domain via the digital to analog converter 313, (iii) amplify the first processed audio signal to provide an amplified audio output signal in the analog domain; and (iv) output the amplified audio output signal via the output circuit 314 to drive the one or more loudspeakers 106.

In operation 406, the audio bus to analog converter 302 is programmed to convert the processed audio input signal (e.g., the output of the network physical layer 310) into a second processed audio signal in the analog domain.

In operation 408, the measurement controller 201 is programmed to determine a delay (e.g., T1+T2+T3) for the amplifier 104 to (i) process the audio input signal (e.g., T1), (ii) convert the processed audio input signal into the first processed audio signal (e.g., T2), (iii) amplify the first processed audio signal, and (iv) output the amplified audio output signal based at least on the first processed audio signal being in the analog domain and the outputted amplified audio output signal being in the analog domain.

It is recognized that the controllers as disclosed herein may include various microprocessors, integrated circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, such controllers as disclosed utilizes one or more microprocessors to execute a computer-program that is embodied in a non-transitory computer readable medium that is programmed to perform any number of the functions as disclosed. Further, the controller(s) as provided herein includes a housing and the various number of microprocessors, integrated circuits, and memory devices ((e.g., FLASH, random access memory (RAM), read only memory (ROM), electrically programmable read only memory (EPROM), electrically erasable programmable read only memory (EEPROM)) positioned within the housing. The controller(s) as disclosed also include hardware-based inputs and outputs for receiving and transmitting data, respectively from and to other hardware-based devices as discussed herein.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. An audio system for measuring a delay, the audio system comprising:
an audio controller programmed to transmit an audio input signal in a digital domain;
an amplifier programmed to:
process the audio input signal;
convert the processed audio input signal into a first processed audio signal in an analog domain;
amplify the first processed audio signal to provide an amplified audio output signal in the analog domain; and
output the amplified audio output signal to drive one or more loudspeakers;
a first digital to analog converter programmed to convert the processed audio input signal into a second processed audio signal in the analog domain; and
a measurement controller programmed to determine a delay for the amplifier to (i) process the audio input signal, (ii) convert the processed audio input signal into the second processed audio signal, (iii) amplify the first processed audio signal, and (iv) output the amplified audio output signal based at least on the first processed audio signal being in the analog domain and the outputted amplified audio output signal being in the analog domain.

2. The audio system of claim 1, wherein the measurement controller is further programmed to determine a first time period corresponding to a first amount of time the amplifier processes the audio input signal.

3. The audio system of claim 2, wherein the measurement controller is further programmed to determine a second time period corresponding to a second amount of time the first digital to analog converter converts the processed audio input signal into the second processed audio signal in the analog domain.

4. The audio system of claim 3, wherein the measurement controller is further programmed to determine a third time period corresponding to a third amount of time the amplifier amplifies the first processed audio signal and outputs the amplified audio output signal.

5. The audio system of claim 4, wherein the measurement controller is further programmed to determine the delay for the amplifier based on a sum of the first time period, the second time period, and the third time period.

6. The audio system of claim 1, wherein the amplifier includes a network physical layer programmed to process the audio input signal.

7. The audio system of claim 6, wherein the amplifier includes a second digital to analog converter programmed to convert the processed audio input signal into the first processed audio signal in the analog domain.

8. The audio system of claim 7, wherein the amplifier includes an output circuit configured to amplify the first processed audio signal.

9. A method for measuring a delay in an audio system, the method comprising:
transmitting an audio input signal in a digital domain;
processing, at an amplifier, the audio input signal;
converting the processed audio input signal into a first processed audio signal in an analog domain;
amplifying, by the amplifier, the first processed audio signal to provide an amplified audio output signal in the analog domain;
outputting the amplified audio output signal to drive one or more loudspeakers;
converting, by a first digital to analog converter, the processed audio input signal into a second processed audio signal in the analog domain; and
determining a delay for the amplifier to (i) process the audio input signal, (ii) convert the processed audio input signal into the first processed audio signal, (iii) amplify the first processed audio signal, and (iv) output the amplified audio output signal based at least on the first processed audio signal being in the analog domain and the outputted amplified audio output signal being in the analog domain.

10. The method of claim 9 further comprising determining a first time period corresponding to a first amount of time the amplifier processes the audio input signal.

11. The method of claim 10 further comprising determining a second time period corresponding to a second amount of time the first digital to analog converter converts the processed audio input signal into the second processed audio signal in the analog domain.

12. The method of claim 11 further comprising determining a third time period corresponding to a third amount of time the amplifier amplifies the first processed audio signal and outputs the amplified audio output signal.

13. The method of claim 12 further comprising determining the delay for the amplifier based on a sum of the first time period, the second time period, and the third time period.

14. The method of claim 9, wherein processing, at the amplifier, the audio input signal includes processing, at a network physical layer, the audio input signal.

15. The method of claim 14, wherein converting the processed audio input signal into the first processed audio signal in the analog domain further includes converting the processed audio input signal, by a second digital to analog converter, into the first processed audio signal in the analog domain.

16. A computer-program product embodied in a non-transitory computer readable medium stored in memory that is programmed and executable by at least one controller in an audio system, the computer-program product comprising instructions to:
transmit an audio input signal in a digital domain;
process, at an amplifier, the audio input signal;
convert the processed audio input signal into a first processed audio signal in an analog domain;
amplify, by the amplifier, the first processed audio signal to provide an amplified audio output signal in the analog domain; and
output the amplified audio output signal to drive one or more loudspeakers; and
convert, by a first digital to analog converter, the processed audio input signal into a second processed audio signal in the analog domain; and
determine a delay for the amplifier to (i) process the audio input signal, (ii) convert the processed audio input signal into the first processed audio signal, (iii) amplify the first processed audio signal, and (iv) output the amplified audio output signal based at least on the first processed audio signal being in the analog domain and the outputted amplified audio output signal being in the analog domain.

17. The computer-program product of claim 16 further comprising determining a first time period corresponding to a first amount of time the amplifier processes the audio input signal.

18. The computer-program product of claim 17 further comprising determining a second time period corresponding to a second amount of time the first digital to analog converter converts the processed audio input signal into the second processed audio signal in the analog domain.

19. The computer-program product of claim 18 further comprising determining a third time period corresponding to a third amount of time the amplifier amplifies the first processed audio signal and outputs the amplified audio output signal.

20. The computer-program product of claim 19 further comprising determining the delay for the amplifier based on a sum of the first time period, the second time period, and the third time period.
